(19) United States
(12) Patent Application Publication
(10) Pub. No.: US 2008/0192543 A1
(43) Pub. Date: Aug. 14, 2008

(54) Method and Apparatus for Selecting Redundant Memory Cells

(75) Inventors: Jungwon Kim, South Burlington, VT (US); Jiho Kim, South Burlington, VT (US); Changduk Kim, South Burlington, VT (US)

Correspondence Address: EDELL, SHAPIRO & FINNAN, LLC, 1901 RESEARCH BLVD., SUITE 400, ROCKVILLE, MD, 20850, US

(73) Assignee: Qimonda North America Corp., Cary, NC (US)

(21) Appl. No.: 11/673,771

(22) Filed: Feb. 12, 2007

(51) Int. Cl. G11C 16/06

(52) U.S. Cl. 365/185.09

(57) ABSTRACT

In a semiconductor memory which comprises a main memory array, redundant memory cells, and a plurality of repair fuse boxes, a method of selecting redundant memory cells in relation to repair fuse boxes, comprising testing redundant memory cells to determine whether they are valid or defective, and making a selection of redundant memory cells which allocates valid redundant memory cells to respective repair fuse boxes but which does not allocate defective redundant memory cells to any repair fuse boxes.

### FIELD OF THE INVENTION

The present invention relates to redundant memory cells and repair fuse boxes in semiconductor memories, and particularly to making a selection of redundant memory cells in relation to repair fuse boxes.

### BACKGROUND OF THE INVENTION

In the electrical testing of semiconductor memories before they are delivered to the customer, some of the memory cells in the main memory array are typically found to be defective. To remedy this problem, a bank of redundant memory cells is held in reserve, and each defective memory cell, after it is identified, is in effect replaced with a redundant memory cell.

In order to replace a defective memory cell with a redundant cell, the address of the defective memory cell must be provided. This is done with the use of a repair fuse box having a number of fuses which can be programmed with the address of the defective cell. In the prior art, each redundant memory cell is associated with its own separate repair fuse box.

The fuse boxes, however, are not capable of being miniaturized to the same extent as most of the rest of the semiconductor memory. This is because, for example, in the case of laser activated fuse boxes, the action of the laser in cutting the fuses requires a certain minimum amount of space. Because most of the memory is being progressively miniaturized, over time the fuse box layout is occupying an increasing proportion of the space in semiconductor memories. This is exacerbated by the fact that it is usual for some of the redundant memory cells to themselves be defective, and in the prior art each redundant cell is associated with its own fuse box regardless of whether the redundant cell is defective or not. Thus, there is wasted space in the fuse box layout of prior art semiconductor memories.

### SUMMARY OF THE INVENTION

In accordance with the present invention, a method of selecting redundant memory cells in a semiconductor memory is provided which comprises testing redundant memory cells to determine whether they are valid or defective, and making a selection of such cells which allocates valid redundant cells to respective repair fuse boxes but which does not allocate defective redundant memory cells to any repair fuse boxes.

### BRIEF DESCRIPTION OF THE DRAWINGS

The invention will be better understood by referring to the accompanying drawings wherein:

FIG. 1 shows a prior art repair fuse box layout.

FIG. 2 shows an example of a fuse box layout in accordance with an embodiment of the invention

FIGS. 3(a) to 3(d) show a fuse selector in accordance with an embodiment of the invention in different programming states along with corresponding selections of redundant memory cells.

FIG. 5 is a flow chart depicting the testing of redundant memory cells.

FIG. 6 is a block diagram of a system for replacing defective main memory cells with redundant cells in accordance with an embodiment of the invention.

FIG. 7 shows more detail of part of the system of FIG. 6.

### DETAILED DESCRIPTION

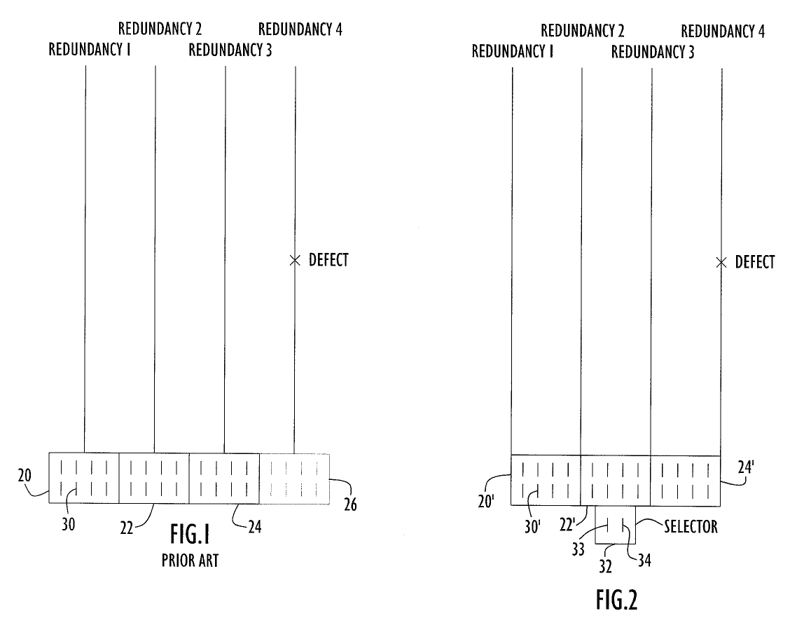

FIG. 1 shows a repair fuse box layout of the prior art. Representative repair fuse boxes 20, 22, 24, and 26 are depicted, and these four fuse boxes are typically only a small portion of the total number of fuse boxes which are used in the memory. Each fuse box contains a number of fuses 30 which may be programmed with the address of a defective memory cell in the main memory array. In order to accomplish the programming, the fuses are selectively cut so that an address is encoded in the fuse set. There are generally two types of fuses used, either laser fuses in which a laser effects the cutting, or current fuses in which an overload of current ruptures the fuse. Laser fuses are generally used in dynamic random access memories (DRAMS), but the present invention is not limited to any particular type of fuse. One of the fuses may serve as a master fuse which must be cut if the fuse box is to contain the address of a defective memory cell.

As described above, the main memory array undergoes electrical testing in order to ensure it's functionality. As a result of such testing, typically a number of memory cells are found to be defective. A bank of redundant memory cells is maintained in the memory, and the defective cells are in effect replaced with redundant cells. The addresses of the defective cells are programmed into respective repair fuse boxes, and when the address of a defective cell is entered for the reading or writing of data this is recognized by the corresponding repair fuse box, which accesses a redundant memory cell, also referred to herein as a “redundancy”.

As will be seen by referring to FIG. 1, in the example given there are four fuse boxes and four redundancies, namely redundancies 1, 2, 3, and 4. That is, in the prior art, there is a one to one correspondence between the number of repair fuse boxes and the number of redundancies. However, some of the redundancies themselves are typically defective. For instance, in the example of FIG. 1, it is redundancy 4 which is noted to have a defect. Since redundancy 4 is associated with fuse box 26, this fuse box 26 is useless and its presence in the memory wastes space.

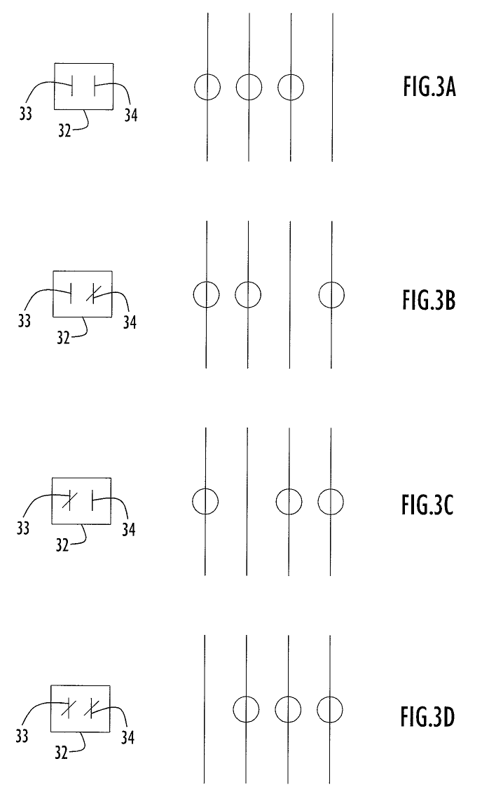

FIG. 2 shows an embodiment which is useful in illustrating the principle of the invention. The four fuse boxes of FIG. 1 have been replaced with three fuse boxes 20′, 22′, and 24′, each containing a number of fuses 30′, wherein each fuse box is associated with two redundancies instead of one. Additionally, after testing of the redundancies to determine which are defective, a selector 32 selects only the valid redundancies and allocates them to respective fuse boxes, while defective redundancies such as redundancy 4 in FIG. 2 are not allocated to any fuse box.

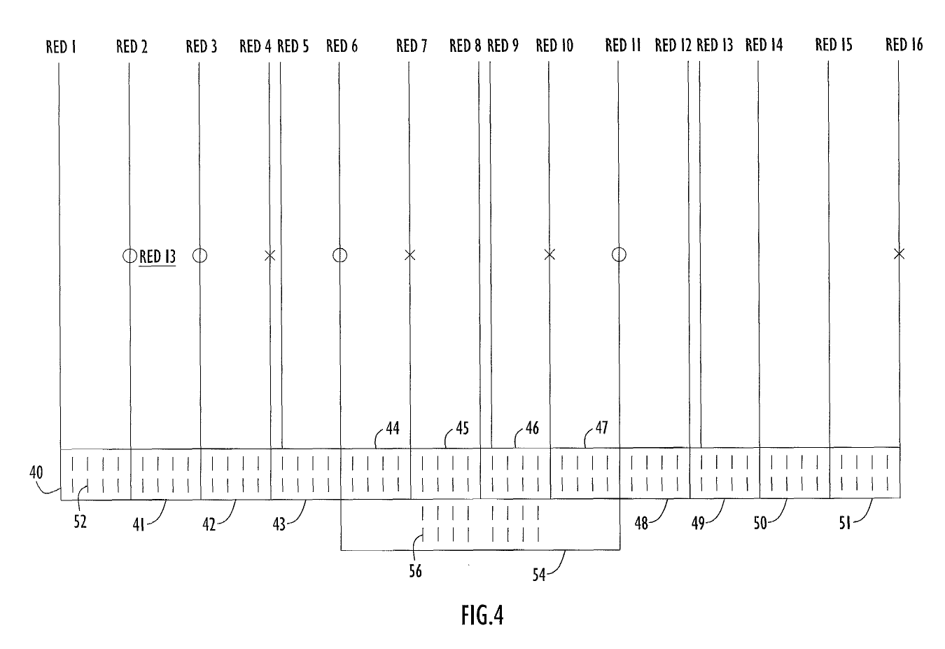

In the preferred embodiment, the selector 32 is provided with a number of fuses, and in the example of FIG. 2, since there are four redundancies, two fuses 33 and 34 may be used. FIGS. 3(a) to 3(d) depicts how the fuses 33 and 34 may be cut to achieve selection of any three of redundancies 1 to 4. Thus, in FIG. 3(a), neither fuse 33 nor fuse 34 is cut, which in accordance with the coding scheme which is used, signifies selection of redundancies 1 to 3. In FIG. 3(b), fuse 34 is cut while fuse 33 is not cut, which correlates with a selection of redundancies 1, 2, and 4. On the other hand, in FIG. 3(c), fuse 33 is cut while fuse 34 is not cut, signifying selection of redundancies 1, 3, and 4. Finally, in FIG. 3(d), both fuses 33 and 34 are cut, which signifies the selection of redundancies 2, 3, and 4. In FIGS. 3(a) to 3(d) the four redundancies are shown to the right of selectors and those redundancies which are selected are overdrawn with a circle. It should be understood that the coding scheme of the selector fuses is arbitrary and may be changed, for example two cut fuses may represent a selection of redundancies 1, 2, and 3, instead of redundancies 2, 3, and 4 so long as the coding scheme which is established is consistently followed.

In the example of FIG. 2, the total number of fuse boxes is divided into groups of three fuse boxes with four redundancies as shown, and each selector would have two fuses. Since every four fuse boxes in the prior art embodiment have been replaced with three fuse boxes, a 25% savings in the space occupied by the fuse box layout has been achieved in this example by adding a selection capability. This is based on the underlying assumption that there is a greater than 25% failure rate in the redundant memory cells. If a smaller failure rate is assumed, then a larger number of fuse boxes would need to be used.

Additionally, various combinations of fuse groupings and redundancies with selectors having different number of fuses are possible, all of which fall within the scope of the invention.

One such illustrative example is shown in FIG. 4. In this example, there are twelve fuse boxes, 40 to 51 containing fuses 52, and sixteen redundancies, 1 to 16. Thus, the ratio of three fuse boxes for every four redundancies as in FIG. 2 has been maintained, it being understood that other ratios may be used as well. The selector 54 contains a plurality of fuses 56, sufficient in number to program the selector in a desired manner.

Two sets of redundancy defects are depicted in FIG. 4, the first being represented by x's, and the second being represented by o's. In the set of defects represented by x's, the defects are about evenly distributed across the fuse boxes, there being one defect for every three successive fuse boxes. The fuses in selector 54 would be programmed so as not to use defective redundancies 4, 7, 1 0, and 16, and the valid redundancies would be allocated to fuse boxes as in FIG. 2. In the set of redundancy defects depicted by o's, the defects are not evenly distributed across the fuse boxes. Thus, successive redundancies 2 and 3 have defects while the last four redundancies 13, 14, 15, and 16 have no defects. In this situation, since fuse box 41 is unused and there are not enough fuse boxes to accommodate redundancies 13 to 16, one of such redundancies such as redundancy 13 is allocated to fuse box 41. Thus, when enough selector fuses are used, any desired combination of redundancies with fuse boxes can be provided.

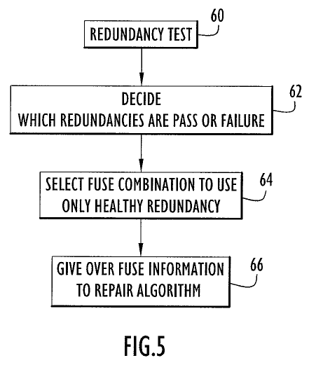

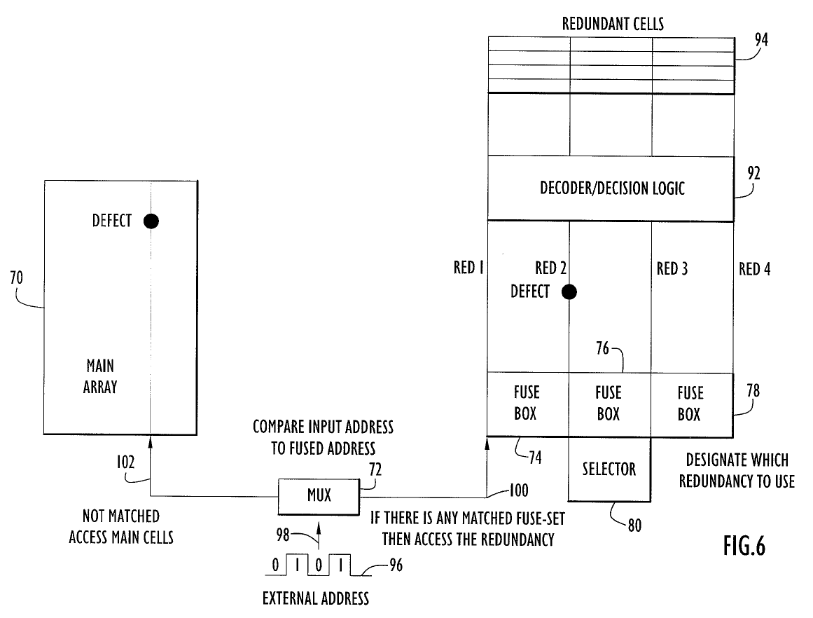

FIG. 5 is a flow chart of the redundancy testing. At step 60, each redundant cell in the redundancy bank is tested to determine if it is valid or defective. Each redundant cell has a virtual address which may be accessed in the test mode only. In order to perform the test, each redundant cell is accessed by it's virtual address, and data is written to the cell and read from it. At step 62 a decision is made to determine if the cell is functional, that is if it has passed or failed the test, so the defective redundancies are now identified. At step 64, redundancies are allocated to fuses in such manner that only healthy redundancies are used. Additionally, the allocation may be such that a minimum number of fuses are left unused. At step 66, the redundancy/fuse information is provided to the repair algorithm, as is discussed further in connection with FIG. 6.

FIG. 6 is a block diagram of a memory system for accessing redundancies during operation of the memory. The blocks shown are main memory array 70, multiplexer 72, fuse boxes 74, 76, and 78, selector 80, decoder/decision logic 92, and redundant cell bank 94. Additionally, multiplexer 72 receives an external address 96 as depicted by arrow 98 and the multiplexer communicates with the fuse boxes on line 100 and with the main array on line 102. The memory may be of the DRAM type, but the invention is not limited to this type of semiconductor memory.

Before the system can operate, the redundant cells in bank 94 are tested for defects in accordance with the flow chart of FIG. 5 and the selector 80 is programmed so that only healthy redundancies are allocated to fuse boxes. In the example of FIG. 6, redundancy 2 has a defect and is discarded while redundancies 1, 3, and 4 are allocated to fuse boxes 74, 76, and 78 respectively. The repair algorithm comprises these allocations which are set in the decision logic portion of decoder/decision logic 92. Also, the locations of defects in the main array are programmed into the fuse boxes 74, 76 and 78 by cutting a combination of fuses which corresponds to the addresses of the defects in the main array.

In the operation of the memory, an external address 96 corresponding to the location of a main memory cell is fed to multiplexer 72 as depicted by arrow 98. The multiplexer feeds the address to the fuse boxes on line 100, and the address is compared to each address programmed into the fuse boxes to see if there is a match. If a match is found, then the appropriate redundancy is accessed, but if there's no match, multiplexer 72 feeds the address to the main array to access the appropriate cell in the usual manner. If there is an address match with a fuse box, the decoder/decision logic 92 recognizes the location of the fuse box and accesses the particular redundancy in redundancy bank 94 which has been predetermined by the selector 80.

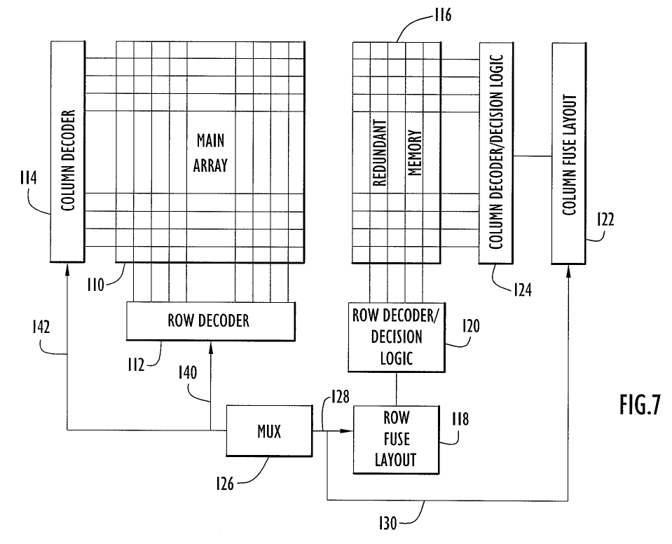

FIG. 7 is a block diagram which shows parts of the diagram of FIG. 6 in greater detail. The blocks in FIG. 7 are main memory array 110, row decoder 112, column decoder 114, redundant memory cell bank 116, row fuse layout 118 including fuse boxes and selector, row decoder/decision logic 120, column fuse layout 122, column decoder/decision logic 124, and multiplexer 126. In an actual embodiment, the fuse boxes shown in FIG. 6 could be comprised of row fuse boxes and column fuse boxes. Thus, the row address of the main array defect would be programmed into the row fuse box and the column address of the defect would be programmed into the column fuse box.

Referring to FIG. 7, a match to an incoming address would be determined when there is a match to both a row fuse box in layout 118 and to a column fuse box in layout 122. The row decoder/decision logic 120 and column decoder/decision logic 124 determine the combination of redundancies and fuses which will be used, and when a row/column match is determined, the appropriate redundancies are correlated with the respective fuse boxes.

In the operation of the memory, multiplexer 126 is fed with an external address, which is fed on lines 128 and 130 to the row and column fuse box layouts. If there is a match of the addresses to both a row and column fuse box, a redundancy is accessed. If there is no match, the address is fed to row decoder 112 on line 140, and to column decoder 114 on line 142 of the main memory for accessing a main memory cell.

There thus has been provided a method and semiconductor memory for selecting redundancies in relation to repair fuse boxes. While the invention has been described in connection with illustrative embodiments, it should be understood that variations which come within the scope of the invention will occur to those skilled in the art. Thus, the invention is to be limited only by the claims appended hereto and equivalents.

What is claimed is:

1. In a semiconductor memory which comprises a main memory array, redundant memory cells, and a plurality of repair fuse boxes, a method of selecting redundant memory cells in relation to repair fuse boxes, comprising:
testing redundant memory cells to determine whether they are valid or defective; and
making a selection of redundant memory cells which allocates valid redundant memory cells to respective repair fuse boxes but which does not allocate defective redundant memory cells to any repair fuse boxes.

2. The method of claim 1 wherein the valid redundant memory cells which are allocated to respective repair fuse boxes are each allocated to a different repair fuse box.

3. The method of claim 2 wherein the selection of redundant memory cells is made by selector fuses which have been programmed to make said selection.

4. The method of claim 3 wherein testing a redundant memory cell comprises accessing said redundant cell, writing data to the redundant cell, and reading said data to determine if the redundant cell is functional.

5. The method of claim 4 wherein the memory contains fewer repair fuse boxes than redundant memory cells.

6. A semiconductor memory containing a main memory cell array, redundant memory cells, and a plurality of repair fuse boxes, wherein there are fewer repair fuse boxes than redundant memory cells and wherein there is a selector for allocating certain of the redundant memory cells to respective fuse boxes.

7. The memory of claim 6 wherein said certain of the redundant memory cells which are allocated to fuse boxes have been determined by testing to be valid redundant cells.

8. The memory of claim 6 wherein the selector comprises a plurality of fuses.

9. The memory of claim 7 wherein there is a predetermined ratio of fuse boxes to redundant memory cells which is dependent on the expected percentage of valid redundant cells in the memory.

10. The memory of claim 9 wherein each repair fuse box is programmed with the address of a defective cell in the main memory cell array and wherein there is a comparator for comparing incoming addresses with the programmed addresses in the fuse boxes to find a match.

11. A semiconductor memory containing a main memory cell array, redundant memory cells, and a plurality of repair fuse boxes, there being fewer repair fuse boxes than redundant memory cells, and a selector comprised of a plurality of fuses for allocating redundant memory cells which have been determined to be valid to respective fuse boxes.

12. The memory of claim 11 wherein fuses in the selector are cut in accordance with a predetermined coding scheme to determine which redundant memory cells are allocated to which repair fuse boxes.

13. The memory of claim 12 wherein there is a predetermined ratio of fuse boxes to redundant memory cells which is dependent on the expected percentage of valid redundant cells in the memory.

14. The memory of claim 13 wherein there are three repair fuse boxes for every four redundant memory cells.

15. The memory of claim 14 wherein there is a selector for every three fuse boxes and wherein the selector contains two fuses.

16. An apparatus for selecting redundant memory cells in a semiconductor memory in relation to repair fuse boxes which are also contained in the memory, comprising:
means for testing redundant memory cells to determine if they are valid or defective; and
means for making a selection of redundant memory cells which allocates valid redundant memory cells to respective repair fuse boxes but which does not allocate defective redundant memory cells to any repair fuse boxes.

17. The apparatus of claim 16 wherein the means for making a selection of redundant memory cells allocates each memory cell to a different repair fuse box.

18. The apparatus of claim 17 wherein said means for making a selection comprises selector fuses which have been programmed to make the selection.

19. The apparatus of claim 18 wherein the means for testing a redundant memory cell comprises means accessing a redundant cell, means for writing data to said redundant cell, and means for reading the data which has been written to the redundant cell.

20. The apparatus of claim 19 wherein the memory contains fewer repair fuse boxes than redundant memory cells.

21. In a semiconductor memory which includes a main memory cell array, redundant memory cells and a plurality of repair fuse boxes, a method of replacing defective cells in the main memory array with redundant cells comprising the steps of:
testing the cells of the main memory cell array to determine defective main memory cells;
programming the repair fuse boxes with the addresses of the defective main memory cells;
testing redundant memory cells to determine whether they are valid or defective;
making a selection of redundant memory cells which allocates valid redundant memory cells to respective repair fuse boxes but which does not allocate defective redundant memory cells to any repair fuse boxes;
comparing the address indicative of a main memory cell to be accessed with the addresses programmed in the repair fuse boxes;
if a match is found, accessing the redundant memory cell which has been allocated to the repair fuse box which provided the match; and
if no match is found, accessing the main memory cell which corresponds to said address.

22. The method of claim 21 wherein the valid redundant memory cells which are allocated to respective repair fuse boxes are each allocated to a different repair fuse box.

23. The method of claim 22 wherein the selection of redundant memory cells is made by programming selector fuses.

24. The method of claim 21 wherein testing a redundant memory cell comprises accessing a redundant cell, writing data to the redundant cell, and reading said data to determine if the redundant cell is valid.

25. The method of claim 21 wherein the memory contains fewer repair fuse boxes than redundant memory cells.
